(19) United States
(12) Patent Application Publication
(10) Pub. No.: US 2025/0176317 A1
(43) Pub. Date: May 29, 2025

(54) LIGHT-EMITTING DIODE AND LIGHT-EMITTING DEVICE

(71) Applicant: XIAMEN SAN'AN OPTOELECTRONICS CO., LTD., Xiamen (CN)

(72) Inventors: JIANGBIN ZENG, Xiamen (CN); GUANGYAO WU, Xiamen (CN); KAI ZHAO, Xiamen (CN); CHAO LU, Xiamen (CN); QING WANG, Xiamen (CN); LING-YUAN HONG, Xiamen (CN); SHAO-HUA HUANG, Xiamen (CN); CHI-MING TSAI, Xiamen (CN); CHUNG-YING CHANG, Xiamen (CN)

(21) Appl. No.: 18/953,060

(22) Filed: Nov. 20, 2024

(30) Foreign Application Priority Data
Nov. 23, 2023 (CN) 2023115759790

(51) Int. Cl. H01L 33/38; H01L 33/42; H01L 33/46; H01L 33/62

(52) U.S. Cl. CPC H10H 20/831; H10H 20/833; H10H 20/841; H10H 20/857

(57) ABSTRACT

A light-emitting diode (LED) includes a semiconductor laminated layer including a first semiconductor layer, a light-emitting layer, and a second semiconductor layer arranged sequentially; a transparent conductive layer disposed on an upper surface of the second semiconductor layer; and an insulating structure, covering the semiconductor laminated layer and the transparent conductive layer. The insulating structure defines a first opening and a second opening, the first opening is located on the first semiconductor layer, and the second opening is located on the transparent conductive layer. The transparent conductive layer defines a groove corresponding to the second opening. With this arrangement, the electrostatic discharge resistance and light-emitting performance of the LED can be effectively enhanced and the quality of the LED can be improved.

### CROSS-REFERENCE TO RELATED APPLICATION

This application claims priority to Chinese Patent Application No. 202311575979.0, filed Nov. 23, 2023, which is herein incorporated by reference in its entirety.

### TECHNICAL FIELD

The disclosure relates to the field of semiconductor manufacturing technologies, and more particularly to a light-emitting diode (LED) and a light-emitting device.

### BACKGROUND

LED is a semiconductor light-emitting element, typically made from a semiconductor such as gallium nitride (GaN), gallium arsenide (GaAs), gallium phosphide (GaP), and gallium arsenide phosphide (GaAsP), etc. The core of the LED is a PN junction with light-emitting properties. The LED has advantages such as high light intensity, high efficiency, small size, and long service life, and is considered one of the most promising light sources currently available. The LED has been widely applied in various fields, including lighting, surveillance and command, high-definition broadcasting, high-end cinemas, office display, conference interaction, and virtual reality etc.

In the application field of mini RGB flip chip technology, manufacturers have higher demands for the mini RGB flip chip. The mini RGB flip chip often have weaker antistatic performance and lower brightness due to its small size, which do not meet current usage requirements. Therefore, how to enhance the antistatic performance and light-emitting performance of the mini LED has become one of the urgent problems to be solved in this field.

It should be noted that the information disclosed in the background technology section is solely intended to enhance the overall understanding of the disclosure and should not be construed as an acknowledgment or any form of implication that such information constitutes the related art known to those skilled in the field.

### SUMMARY

The disclosure provides a LED, and the LED includes a semiconductor laminated layer, a transparent conductive layer and an insulating structure.

The semiconductor laminated layer includes a first semiconductor layer, a light-emitting layer, and a second semiconductor layer arranged sequentially. The transparent conductive layer is disposed on an upper surface of the second semiconductor layer. The insulating structure covers the semiconductor laminated layer and the transparent conductive layer, the insulating structure defines a first opening and a second opening, the first opening is located on the first semiconductor layer, and the second opening is located on the transparent conductive layer. The transparent conductive layer defines a groove corresponding to the second opening.

The disclosure further provides a light-emitting device, including the LED provided in above embodiment.

The LED and the light-emitting device provided by the embodiments of the disclosure, by defining the groove on the transparent conductive layer, can effectively improve the antistatic performance and light-emitting performance of the LED, and enhance the quality of the LED.

Other features and beneficial effects of the disclosure will be set forth in the subsequent specification, and in part will be apparent from the specification, or may be learned by practice of the disclosure.

### BRIEF DESCRIPTION OF DRAWINGS

To more clearly illustrate the technical solutions of the embodiments or the related art, a brief introduction to the accompanying drawings for the description of the embodiments or the related art is provided below. It is apparent that the accompanying drawings described below are some of the embodiments of the disclosure. For those skilled in the art, without the need for creative effort, other drawings can also be obtained based on these accompanying drawings.

FIG. 1 illustrates a schematic structural diagram of a LED according to an embodiment of the disclosure.

FIG. 2 illustrates a schematic enlarged diagram of an area A in the FIG. 1.

FIG. 3 illustrates a schematic structural diagram of a LED in the related art.

FIG. 4 illustrates a schematic structural diagram of another LED in the related art.

FIG. 5 illustrates a schematic structural diagram of a first stage of preparing a groove according to the embodiment of the disclosure.

FIG. 6 illustrates a schematic structural diagram of a second stage of preparing the groove according to the embodiment of the disclosure.

Description of reference numerals: 10: substrate; 12: semiconductor laminated layer; 121: first semiconductor layer; 122: light-emitting layer; 123: second semiconductor layer; 14: transparent conductive layer; 16: insulating structure; 161: first opening; 162: second opening; 18: groove; 21: first pad electrode; 22: second pad electrode; 31: first inclined side wall; 32: second inclined side wall; H1: depth of groove; H2: thickness of transparent conductive layer; W1: bottom width of groove; M1: first angle; M2: second angle; M3: third angle.

### DETAILED DESCRIPTION OF EMBODIMENTS

To make the objectives, technical solutions, and advantages of embodiments of the disclosure clearer, a clear and complete description of the technical solutions in the embodiments of the disclosure is provided below in conjunction with the accompanying drawings of the embodiments of the disclosure. Apparently, the described embodiments are only part of the embodiments of the disclosure, not all of them. The technical features designed in the different embodiments of the disclosure described below can be combined with each other as long as they do not conflict with each other. Based on the embodiments of the disclosure, all other embodiments obtained by those skilled in the art without creative labor are within the scope of protection of the disclosure.

In the description of the disclosure, it should be understood that terms such as “center”, “transverse”, “on”, “under”, “left”, “right”, “vertical”, “horizontal”, “top”, “bottom”, “inside”, and “outer” etc., which indicate direction or positional relationships, are based on the direction or positional relationships shown in the accompanying drawings. They are used merely for the purpose of describing the disclosure and simplifying the description, rather than indicating or implying that the devices or components referred to must have a specific orientation or be constructed and operated in a specific orientation. Therefore, they should not be understood as limitations on the disclosure. Furthermore, terms “first” and “second” are used for descriptive purposes and should not be understood as indicating or implying relative importance or specifying the number of the technical features indicated. Thus, features specified as “first” or “second” may explicitly or implicitly include one or more such features. In the description of the disclosure, unless otherwise specified, the term “multiple” means two or more. Additionally, the term “include” and its derivatives mean “include at least”.

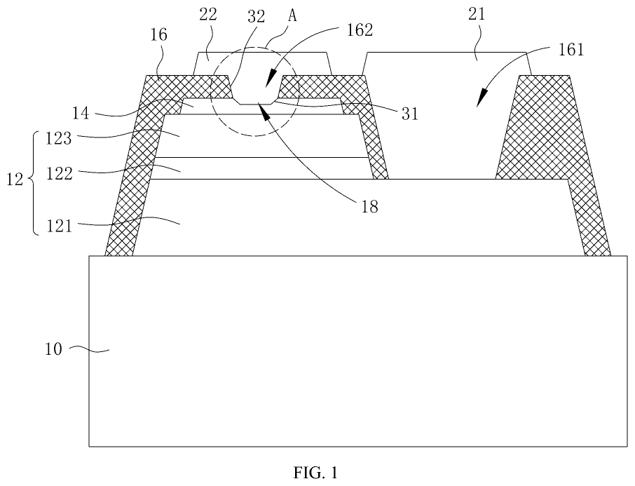

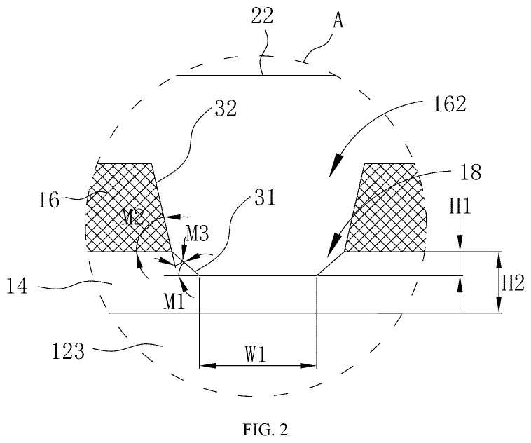

Referring to FIG. 1 and FIG. 2, FIG. 1 illustrates a schematic structural diagram of a LED provided by an embodiment of the disclosure, and FIG. 2 illustrates a schematic enlarged diagram of an area A in the FIG. 1. To achieve at least one of the advantages or other advantages, the embodiment of the disclosure provides the LED. As shown in FIG. 1 and FIG. 2, the LED includes a semiconductor laminated layer 12, a transparent conductive layer 14 and an insulating structure 16.

The semiconductor laminated layer 12 is disposed on a substrate 10. The substrate 10 can be an insulating substrate, preferably, the substrate 10 can be made of a transparent or semi-transparent material. In the embodiment, the substrate 10 is a sapphire substrate. In some embodiments, the substrate 10 can be a patterned sapphire substrate, but the disclosure is not limited to this. The substrate 10 can also be made of a conductive material or semiconductor material. For example, a material of the substrate 10 can include one or more selected from the group consisting of silicon carbide (SiC), silicon (Si), aluminum magnesium oxide, magnesium oxide (MgO), lithium aluminate, aluminum gallium oxide and GaN.

The semiconductor laminated layer 12 includes a first semiconductor layer 121, a light-emitting layer 122, and a second semiconductor layer 123 stacked sequentially on the substrate 10. The light-emitting layer 122 is disposed between the first semiconductor layer 121 and the second semiconductor layer 123.

The first semiconductor layer 121 can be an N-type semiconductor layer, which can provide electrons to the light-emitting layer 122 under the action of a power supply. In some embodiments, the first semiconductor layer 121 includes an N-type doped nitride layer. The N-type doped nitride layer may contain N-type impurities. The N-type impurities can include one or more selected from the group consisting of Si, germanium (Ge), and stannum (Sn).

The light-emitting layer 122 can be a quantum well (QW) structure; in some embodiments, the light-emitting layer 122 can be a multiple quantum well (MQW) structure. The MQW structure includes MQW layers (Well) and multiple quantum barrier layers (Barrier) alternately disposed in a repetitive manner, such as GaN/aluminium gallium nitride (AlGaN), indium aluminum gallium nitride (InAlGaN)/InAlGaN, or indium gallium nitride (InGaN)/AlGaN MQW structures. In addition, a composition and a thickness of well layers within the light-emitting layer 122 determine a wavelength of generated light. To improve the light-emitting efficiency of the light-emitting layer 122, it can be achieved by changing the depth of the quantum wells, the number, thickness and/or other characteristics of paired quantum wells and quantum barriers in the light-emitting layer 122.

The second semiconductor layer 123 can be a P-type semiconductor layer, which can provide holes to the light-emitting layer 122 under the action of the power supply. In some embodiments, the second semiconductor layer 123 includes a P-type doped nitride layer. The P-type doped nitride layer may contain one or more P-type impurities. The P-type impurities can include one or more selected from the group consisting of magnesium (Mg), zinc (Zn), and beryllium (Be). The second semiconductor layer 123 can be a single-layer structure or a multi-layer structure with different compositions.

The transparent conductive layer 14 is disposed on an upper surface of the second semiconductor layer 123. The transparent conductive layer 14 mainly serves to diffuse current and achieve ohmic contact. The transparent conductive layer 14 can be made of a transparent conductive material, the transparent conductive material may include one or more selected from the group consisting of indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium-doped zinc oxide (GZO), tungsten doped indium oxide (IWO), and zinc oxide (ZnO), but the embodiment is not limited to these.

The insulating structure 16 covers the semiconductor laminated layer 12 and the transparent conductive layer 14. The insulating structure 16 defines a first opening 161 and a second opening 162. The first opening 161 is located on the first semiconductor layer 121, and the second opening 162 is located on the transparent conductive layer 14. A material of the insulating structure 16 includes a non-conductive material. The non-conductive material is preferably an inorganic material or a dielectric material. The inorganic material can include silica. The dielectric material includes an electrically insulating material such as aluminum oxide, silicon nitride, silicon dioxide, titanium oxide, or magnesium fluoride. For example, the insulating structure 16 can be made of silicon dioxide, silicon nitride, titanium oxide, tantalum oxide, niobium oxide, barium titanate, or their combination, and the combination can be a distributed Bragg reflector (DBR) formed by repeatedly stacking two materials with different refractive indices.

The transparent conductive layer 14 defines a groove 18 corresponding to the second opening 162. The groove 18 is sunk from an upper surface of the transparent conductive layer 14 towards a lower surface of the transparent conductive layer 14. By defining the groove 18 on the surface of the transparent conductive layer 14, the antistatic performance and light-emitting performance of the LED can be ensured, thereby enhancing the reliability of the LED.

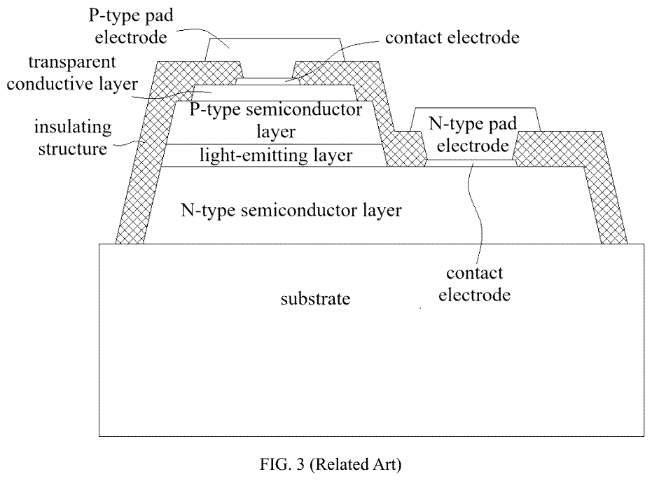

A mini RGB flip chip in the related art is shown in FIG. 3. In an earliest mini LED chip, an N-type semiconductor layer is formed on a substrate, with an exposed mesa on the N-type semiconductor layer. A light-emitting layer is adjacent to the exposed mesa, and a P-type semiconductor layer is disposed on the light-emitting layer. A transparent conductive layer (such as ITO) is disposed on the P-type semiconductor layer. Contact electrodes are formed on the transparent conductive layer and the exposed mesa of the N-type semiconductor layer. After forming the contact electrodes, an insulating structure is formed to cover the contact electrodes, the transparent conductive layer, and the exposed mesa. Openings are defined at positions of the insulating structure corresponding to the contact electrodes, and an N-type pad electrode and a P-type pad electrode are formed on the insulating structure. Since the contact electrodes only cover part of the N-type semiconductor layer and the transparent conductive layer, there is a tilt angle between an edge of the contact electrode and a surface of the transparent conductive layer. Similarly, there is also a tilt angle between an edge of the contact electrode and a side of the N-type semiconductor layer. During the subsequent deposition of the insulating structure, since there are multiple layers and a thickness of the insulating structure is relatively large, the presence of the tilt angles can cause the insulating structure to have corners and protrusions at this location. Additionally, when forming electrode through-holes in the insulating structure, there is also a tilt angle between a side wall of the insulating structure and a surface of each contact electrode, and the corners, the protrusions and the tilt angle on the side wall of the electrode through-hole can result in poor material coverage when forming electrode pads (such as the N-type pad electrode and the P-type pad electrode) on the contact electrodes, resulting in defects such as breaks or cracks, thereby reducing the reliability of the mini LED chip. Furthermore, due to the corners and protrusions of the insulating structure, the electrode pads also have protrusions, leading to an uneven surface of the mini LED chip. During a later die bonding process, height differences on the surface of the mini LED chip can cause poor die bonding, affecting the reliability of the mini LED chip.

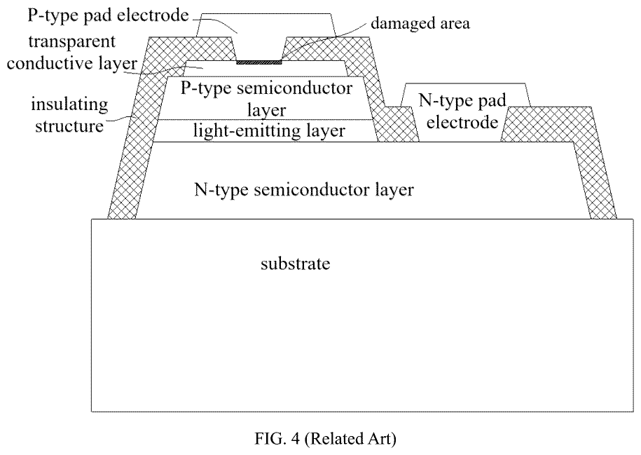

Subsequently, as shown in FIG. 4, to address issues with the Mini LED chip illustrated in FIG. 3, the contact electrodes are no longer formed. Instead, an inductively coupled plasma (ICP) dry etching method is used to process the insulating structure to directly define two openings (such as the first opening 161 and the second opening 162 in this embodiment), and the N pad electrode and P pad electrode are then directly connected to the N-type semiconductor layer and the transparent conductive layer through the openings, respectively. However, the use of the ICP dry etching method can damage the surface of the transparent conductive layer at the opening, forming a damaged area (gases in an ICP process can react with the transparent conductive layer, leading to damage and a generation of a high-resistance material, resulting in the damaged area). A position of the damaged area is roughly indicated by shaded filling. The damaged area can affect the overall performance of the mini LED chip, such as reducing the antistatic performance and light-emitting performance of the mini LED chip.

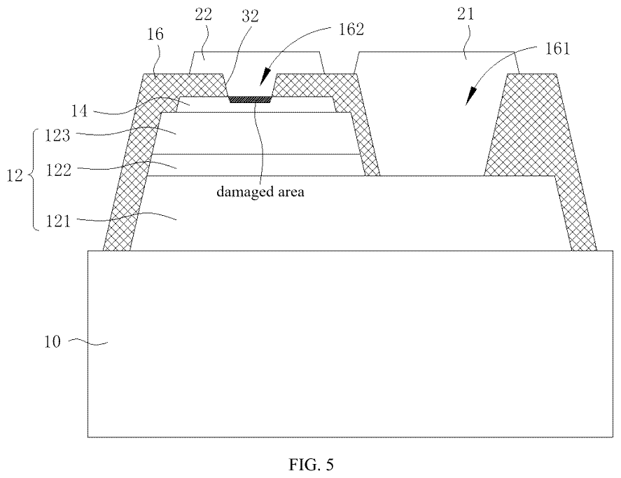

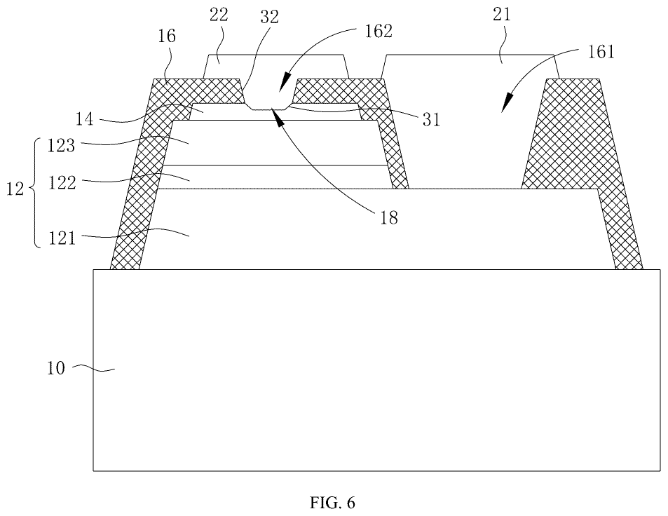

Therefore, the embodiment addresses the issues, by adding treatment in response to the damaged area. For example, another ICP dry etching process can be added to remove the damaged area, the groove 18 is defined and a first inclined side wall 31 is formed by taking advantage of different etching rates of the insulating structure 16 and the transparent conductive layer 14 during the ICP process (due to different materials resulting in different etching rates). The inclination of the first inclined side wall 31 is different from that of a second inclined side wall 32. Specifically, the second opening 162 and the groove 18 are separately formed through two etching steps. First, as shown in FIG. 5, a first etching process targets the insulating structure 16 to define the first opening 161 and the second opening 162. However, an etching gas (i.e., an etching medium) inevitably damages the transparent conductive layer 14, creating a damaged area on the surface of the transparent conductive layer 14 at the second opening 162. Subsequently, as shown in FIG. 6, a second etching process is performed, by using another etching gas specifically designed to remove the damaged area on the surface of the transparent conductive layer 14. At this time, the insulating structure 16 is hardly affected by the another etching gas, and thus the insulating structure 16 is not etched. Moreover, by controlling the time and quantity, etc., of the another etching gas adapted to the material of the transparent conductive layer 14, the etching depth, etching angle and etching area, etc., can be controlled. Therefore, the groove 18 defined by the second etching process can be deeper to remove the damaged area as much as possible and increase an electrode contact area. In addition, theoretically, a first angle M1 can be set to any size, but considering the coverage effect of the electrode and the need to take into account the light-emitting area, the first angle M1 should not be too steep; meanwhile, in order to better remove the damaged area, the first angle M1 should not be too flat.

It should be noted that if only one etching step is used, although a similar groove 18 can be formed by over-etching, an etching gas used for this single etching step is intended for etching the insulating structure 16 to form openings. Therefore, the etching medium (i.e., the etching gas) will continue to damage the transparent conductive layer 14. That is, in the process of etching away the damaged area, a new damaged area will be created, which does not solve the actual technical problem. Moreover, the formation of the groove 18 is inevitable in the first etching process, hence it is impossible to control the depth, angle and size etc., of the groove 18 etched into the transparent conductive layer 14, which is not conducive to ensuring overall performance.

In some embodiments, a longitudinal cross-section of the groove 18 is an inverted trapezoid, which is more effective for ensuring the antistatic performance and light-emitting performance of the LED. In some embodiments, the groove 18 is located below the second opening 162 of the insulating structure 16; for example, when viewed from above, the groove 18 is within an area of the second opening 162. In some embodiments, a maximum thickness of the transparent conductive layer 14 is in a range of 300-3000 Ångstroms (Å), and a depth H1 of the groove 18 is in a range of 200-1000 Å. If the depth H1 is too large, (e.g., greater than 1000 Å), it would remove too much material, excessively affecting the performance of the transparent conductive layer 14. If the depth H1 is too small (e.g., less than 200 Å), the damaged area would not be effectively removed, leading to a decrease in the antistatic performance and light-emitting performance of the LED. Considering the size of the second opening 162, a bottom width W1 of the groove 18 can be less than or equal to 9 μm.

In some embodiments, the transparent conductive layer 14 includes the first inclined side wall 31 surrounding the groove 18, and the insulating structure 16 includes the second inclined side wall 32 surrounding the second opening 162. An angle between the first inclined side wall 31 and a horizontal plane is the first angle M1, and an angle between the second inclined side wall 32 and the horizontal plane is a second angle M2, with both the first angle M1 and the second angle M2 being acute angles less than 90 degrees (°). The first angle M1 is smaller than the second angle M2. However, the disclosure is not limited to this, and in some embodiments, the first angle M1 can be equal to the second angle M2. Comparatively, when the first angle M1 is smaller than the second angle M2, the repair of the transparent conductive layer 14 is more complete, resulting in better overall conductivity and antistatic performance. The first angle M1 can be in a range of 5°-30°. If the first angle M1 is too small (e.g., less than 5°), the damaged area will not be effectively removed, and the performance of the LED will still be compromised; if the first angle M1 is too large (e.g., greater than 30°), it will excessively remove a normal part of the transparent conductive layer 14, leading to issues including uneven current diffusion and poor ohmic contact etc., which are not conducive to ensuring overall performance. The second angle M2 can be in a range of 45°-70°. If the second angle M2 is too small (e.g., less than 45°), it may not leave enough space for the groove 18, and the performance of the LED will still be compromised; if the second angle M2 is too large (e.g., greater than 70°), it will form a relatively vertical side wall, which is not conducive to the subsequent coverage of pad electrodes, and not favorable for enhancing the performance of the LED. Moreover, with the first angle M1 and the second angle M2 within the above ranges, the transparent conductive layer 14 can be better covered, enhancing the stability and reliability of the LED.

In some embodiments, the semiconductor laminated layer 12 further includes a third angle M3, obtained by subtracting the first angle M1 from the second angle M2, and the third angle is in a range of 15°-65°. This third angle M3 can objectively reflect the degree of concavity of the groove 18, i.e., the extent to which the damaged area is repaired. Optionally, the third angle M3 can be in a range of 25°-55°. Within this range, the damaged area can be effectively removed, enhancing the antistatic performance of the LED, while not removing too much of the normal area, ensuring the light-emitting brightness.

The LED further includes a first pad electrode 21 and a second pad electrode 22.

The first pad electrode 21 is electrically connected to the first semiconductor layer 121 through the first opening 161, and the second pad electrode 22 is electrically connected to the transparent conductive layer 14 through the second opening 162. The first pad electrode 21 and the second pad electrode 22 can be single-layer, double-layer, or multi-layer structures, such as titanium (Ti)/aluminium (Al), Ti/Al/Ti/aurum (Au), Ti/Al/nickel (Ni)/Au, vanadium/Al/platinum (Pt)/Au, and other laminated structures. The first pad electrode 21 and the second pad electrode 22 can be metal pads, which can be formed together in a same process using same material, thus having a same layer structure.

In some embodiments, the LED is flip-chip structured. A side length of the LED can be less than 100 μm.

Experimental confirmation is obtained, and experiment data is as follows: Product yields of LED in the related art and the LED of the disclosure at a voltage of 2000 volts (V) are 99.6% and 100%, respectively. At a voltage of 3000 V, the product yields of the LED in the related art and the LED of the disclosure are 99.1% and 100%, respectively. At a voltage of 4000 V, the product yields of the LED in the related art and the LED of the disclosure are 3.9% and 82.1%, respectively. At a voltage of 4500 V, the product yields of the LED in the related art and the LED of the disclosure are 0% and 24.9%, respectively. The experiment data indicates that compared to the LED in the related art, the LED of the disclosure has a higher yield under higher electrostatic discharge conditions, demonstrating that the LED of the disclosure can effectively enhance the antistatic performance.

In summary, the embodiments of the disclosure provide the LED and a light-emitting device, which, by setting the groove 18 on the transparent conductive layer 14, can effectively enhance the antistatic performance and light-emitting performance of the LED, thereby improving the quality of the LED.

Furthermore, those skilled in the art should understand that although there are many problems in the related art, each embodiment or technical solution of the disclosure can be improved in only one or a few aspects, without simultaneously solving all the technical problems listed in the related art or background technology. Those skilled in the art should understand that content not mentioned in a claim should not be used as a limitation on that claim.

Finally, it should be noted that the above embodiments are only used to illustrate the technical solution of the disclosure, and not to limit it. Although the disclosure is described in detail with reference to the embodiments, those skilled in the art should understand that they can still modify the technical solutions described in the embodiments, or equivalently replace some or all of the technical features; And these modifications or amendments do not deviate from the essence of the corresponding technical solutions from the scope of the various embodiments of the disclosure.

What is claimed is:

1. A light-emitting diode (LED), comprising:
a semiconductor laminated layer comprising a first semiconductor layer, a light-emitting layer, and a second semiconductor layer arranged sequentially;
a transparent conductive layer disposed on an upper surface of the second semiconductor layer; and
an insulating structure, covering the semiconductor laminated layer and the transparent conductive layer, wherein the insulating structure defines a first opening and a second opening, the first opening is located on the first semiconductor layer, and the second opening is located on the transparent conductive layer;
wherein the transparent conductive layer defines a groove corresponding to the second opening.

2. The LED as claimed in claim 1, wherein the transparent conductive layer comprises a first inclined side wall surrounding the groove, the insulating structure comprises a second inclined side wall surrounding the second opening, an angle between the first inclined side wall and a horizontal plane is a first angle, an angle between the second inclined side wall and the horizontal plane is a second angle, and the first angle is smaller than the second angle.

3. The LED as claimed in claim 2, wherein the first angle is in a range of 5 degrees (°)-30°.

4. The LED as claimed in claim 2, wherein the second angle is in a range of 45°-70°.

5. The LED as claimed in claim 1, wherein a maximum thickness of the transparent conductive layer is in a range of 300-3000 Ångstroms (Å).

6. The LED as claimed in claim 1, wherein the groove is sunk from an upper surface of the transparent conductive layer towards a lower surface of the transparent conductive layer.

7. The LED as claimed in claim 1, wherein a depth of the groove is in a range of 200-1000 Å.

8. The LED as claimed in claim 1, wherein a bottom width of the groove is less than or equal to 9 micrometers (μm).

9. The LED as claimed in claim 1, wherein the transparent conductive layer comprises a first inclined side wall surrounding the groove, the insulating structure comprises a second inclined side wall surrounding the second opening, an angle between the first inclined side wall and a horizontal plane is a first angle, an angle between the second inclined side wall and the horizontal plane is a second angle, and the first angle is equal to the second angle.

10. The LED as claimed in claim 1, further comprising: a first pad electrode and a second pad electrode, wherein the first pad electrode is electrically connected to the first semiconductor layer through the first opening, and the second pad electrode is electrically connected to the transparent conductive layer through the second opening.

11. The LED as claimed in claim 1, wherein a longitudinal cross-section of the groove is an inverted trapezoid.

12. The LED as claimed in claim 1, wherein the LED is flip-chip structured.

13. The LED as claimed in claim 1, wherein a side length of the LED is less than 100 μm.

14. The LED as claimed in claim 1, wherein the second opening and the groove are formed separately through two etching steps.

15. The LED as claimed in claim 2, wherein a third angle is obtained by subtracting the first angle from the second angle, and the third angle is in a range of 15°-65°.

16. The LED as claimed in claim 2, wherein a third angle is obtained by subtracting the first angle from the second angle, and the third angle is in a range of 25°-55°.

17. A light-emitting device, comprising: the LED as claimed in claim 1.

18. The light-emitting device as claimed in claim 17, wherein the transparent conductive layer comprises a first inclined side wall surrounding the groove, the insulating structure comprises a second inclined side wall surrounding the second opening, an angle between the first inclined side wall and a horizontal plane is a first angle, an angle between the second inclined side wall and the horizontal plane is a second angle, and the first angle is smaller than the second angle.

19. The light-emitting device as claimed in claim 17, wherein the groove is sunk from an upper surface of the transparent conductive layer towards a lower surface of the transparent conductive layer.

20. The light-emitting device as claimed in claim 17, wherein a depth of the groove is in a range of 200-1000 Å.
